(19) United States
(12) Patent Application Publication
(10) Pub. No.: US 2015/0136597 A1
(43) Pub. Date: May 21, 2015

(54) Glass Coating System

(71) Applicant: CSG HOLDING CO., LTD., Shenzhen (CN)

(72) Inventors: Haifeng Chen, Shenzhen (CN); Zhenzhong Bai, Shenzhen (CN)

(73) Assignee: CSG HOLDING CO., LTD., Shenzhen (CN)

(21) Appl. No.: 14/521,343

(22) Filed: Oct. 22, 2014

(30) Foreign Application Priority Data
Nov. 20, 2013 (CN) 201310589013.2

(51) Int. Cl. H01J 37/32; H01J 37/34

(52) U.S. Cl. CPC H01J 37/32733; H01J 37/34
USPC 204/298.23; 269/58

(57) ABSTRACT

A system for coating a glass board is disclosed. The coating system includes a coating chamber, a conveying unit and a support module. The conveying unit is located at a lower portion of the coating chamber and has two rollers for conveying a sheet of glass to be coated. The support module is located between the rollers and has a seat and an elevator connected to the seat. A distance between the seat and the glass can be adjusted by the elevator.

### BACKGROUND OF THE INVENTION

1. Technical Field The invention relates to coating devices, particularly to glass coating devices.

2. Related Art

In recent years, with the execution of national policy of energy conservation and carbon reduction, energy-saving glass has been applied in doors, windows and glass curtain extensively. In a glass sputtering production line, cathodes continuously sputter. Because the glasses to be coated possess different sizes and there is a distance between two adjacent glasses, films will progressively stack up on the seat under the cathode. The films will be thick to be higher than the glass surface in a month. At this time, the glass surface will be scratched or the stacking films will impede the shift of the glass to be slant or even completely stop the glass. Thus the undesired films must be periodically cleaned.

FIG. 1 shows a conventional production line for energy-saving glass coating. The vacuum room la has a sputtering cathode 3a. When the vacuum room la reaches a certain vacuum degree, the sputtering cathode 3a in the chamber 3a starts working to perform sputtering coating. A sheet of glass 7a to be coated is conveyed by a roller 4a under the cathode 3a to be formed with a film. This is vacuum coating. Because the glasses to be coated possess different sizes and there is a distance between two adjacent glasses, films from the cathode will progressively stack up on the seat 6a. The seat 6a is fixed on the bottom 2a of the vacuum room la by screws 5a and cannot be adjusted. When the films are thick enough to be higher than the glass 7a surface, the glass 7a surface will be scratched or the stacking films will impede the shift of the glass to be slant or even completely stop the glass 7a. Thus the undesired films must be periodically cleaned. This seriously reduces production efficiency.

### SUMMARY OF THE INVENTION

An object of the invention is to provide a glass coating system, whose seat can be adjusted to correspond to the stacking films on the seat. Thus the films will not impede the glass to be coated and the production efficiency will be improved.

To accomplish the above object, the coating system of the invention includes a coating chamber, a conveying unit and a support module. The conveying unit is located at a lower portion of the coating chamber and has two rollers for conveying a sheet of glass to be coated. The support module is located between the rollers and has a seat and an elevator connected to the seat. A distance between the seat and the glass can be adjusted by the elevator.

### BRIEF DESCRIPTION OF THE DRAWINGS

FIG. 1 is a schematic view of a conventional glass coating device;

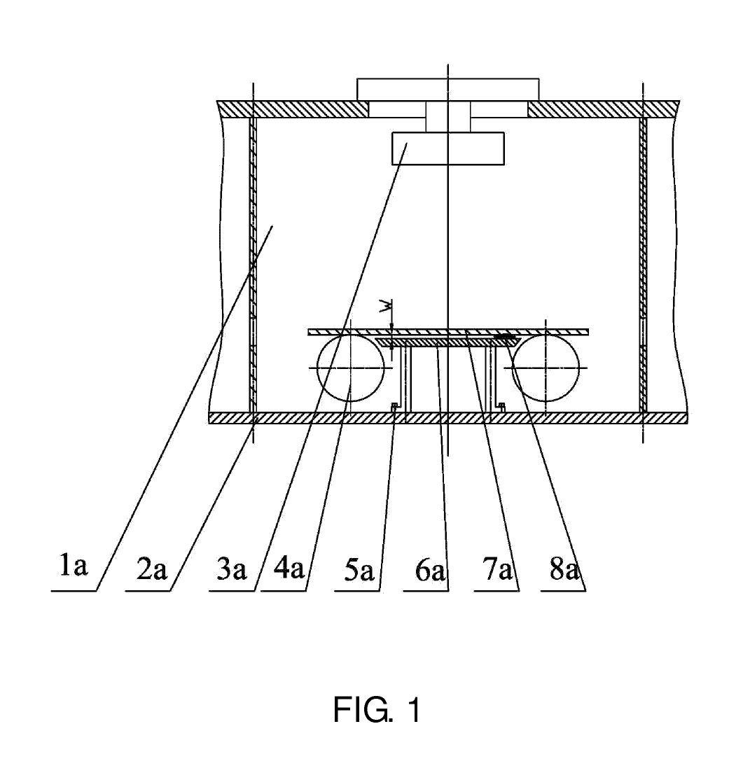

FIG. 2 is a sectional view of the invention; and

FIG. 3 is a schematic view of the elevator of the invention.

### DETAILED DESCRIPTION OF THE INVENTION

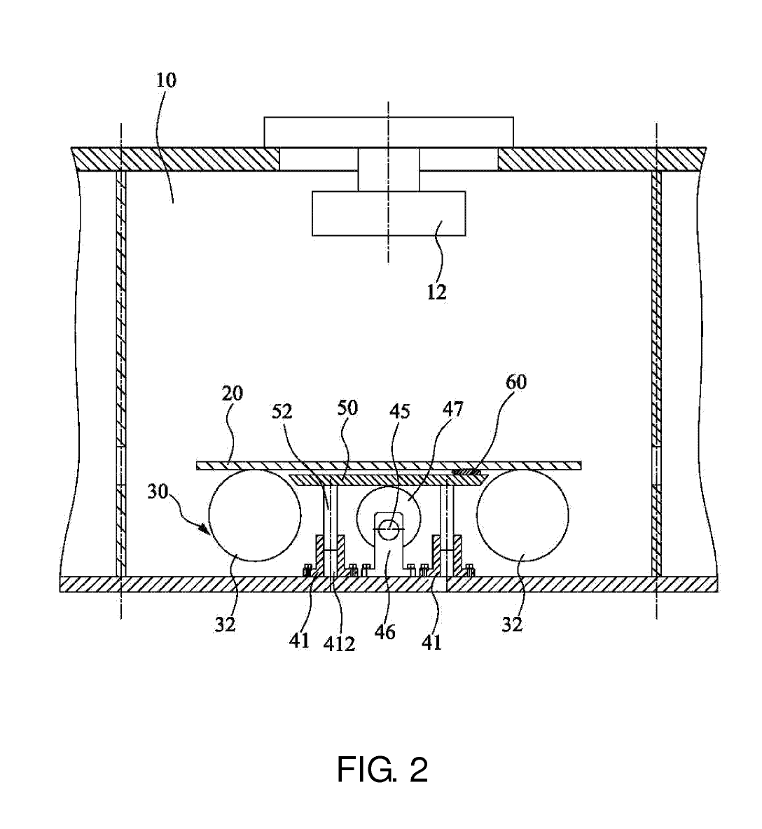

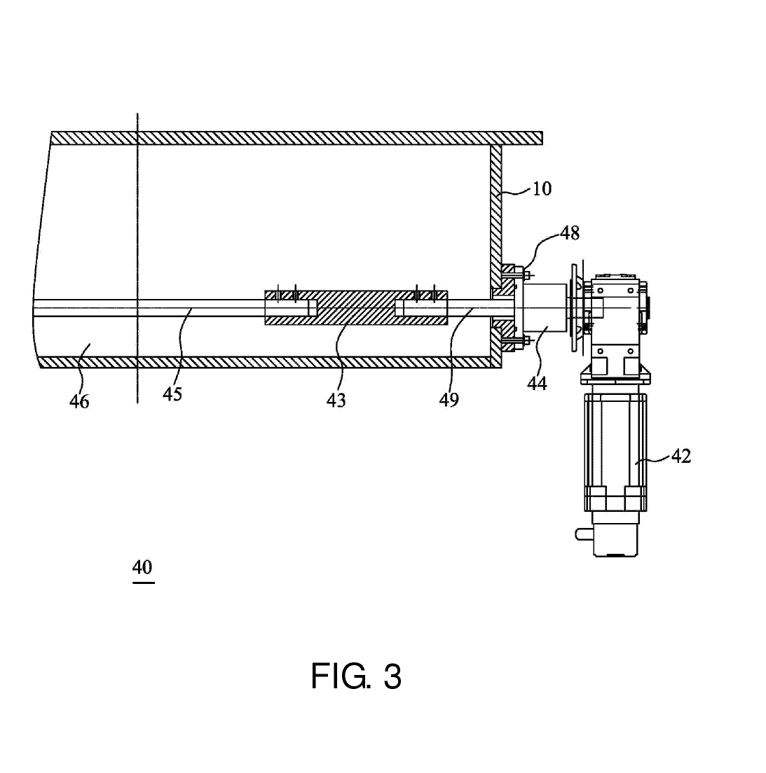

Please refer to FIGS. 2 and 3. The invention provides a system for coating a sheet of glass 20. The system of the invention includes a coating chamber 10, a conveying unit 30 and a support module. The conveying unit 30 is located at a lower portion of the coating chamber 10 and has two rollers 32. The support module is located between the rollers 32 and has a seat 50 and an elevator 40 connected to the seat 50. A distance between the seat 50 and the glass 20 can be adjusted by the elevator 40. A cathode 12 is arranged at an upper portion of the coating chamber 10. The support module is located under the cathode 12.

The elevator 40 includes two fixing bases 41, a servomotor 42 and an eccentric wheel mechanism. The fixing bases 41 are fastened on the bottom of the coating chamber 10. The eccentric wheel mechanism is disposed between the two fixing bases 41. The servomotor 42 is disposed outside the coating chamber 10. A spindle 49 of the servomotor 42 is provided with a coupling 43.

The eccentric wheel mechanism includes a bearing seat 46 between the fixing bases 41. A shaft 45 is disposed in the bearing seat 46. The shaft 45 is disposed with an eccentric wheel 47. The shaft 45 is connected to a spindle 49 through the coupling 43. The shaft 45 can drive the eccentric wheel 47 to rotate. The seat 50 can be moved up or down by rotation of the shaft 50 and the eccentric wheel 47. A sealing ring 48 and a sealing element 44 divide the spindle 49 into an interior portion and an exterior portion to guarantee a vacuum status in the coating chamber and no outside air to enter the coating chamber 10 when the spindle 49 is rotating. The shaft 45 can be rotated by the spindle 49 of the servomotor 42 to move the seat 50 up or down. This allows the seat 50 to be adjustable.

Each of the fixing bases 41 is provided with a guiding trough 412. The bottom of the seat 50 is provided with two guiding rods 52. The guiding rods 52 are separately received in the guiding troughs 412. The eccentric wheel 47 is in contact with the seat 50. By the rotation of the eccentric wheel 47, the guiding rods 52 can move up or down in the guiding troughs 412 to move the seat 50 up or down.

A sealing ring 48 is disposed between the coating chamber 10 and the spindle 49 of the servomotor 42. A sealing element 44 is disposed between the spindle 49 and the sealing ring 48. The sealing ring 48 and the sealing element 44 divide the spindle 49 into an interior portion and an exterior portion to guarantee the vacuum degree of the coating chamber 10. The shaft 45 is synchronously driven with the spindle 49 so as to adjust the seat 50 in vacuum.

Please refer to FIGS. 2 and 3. The support module has a seat 50 and an elevator 40 connected to the seat 50. A distance between the seat 50 and the glass 20 can be adjusted by the elevator 40. A cathode 12 is arranged at an upper portion of the coating chamber 10. The support module is located under the cathode 12.

The eccentric wheel mechanism includes a bearing seat 46 between the fixing bases 41. A shaft 45 is disposed in the bearing seat 46. The shaft 45 is disposed with an eccentric wheel 47. The shaft 45 is connected to a spindle 49 through the coupling 43. The shaft 45 can drive the eccentric wheel 47 to rotate.

Each of the fixing bases 41 is provided with a guiding trough 412. The bottom of the seat 50 is provided with two guiding rods 52. The guiding rods 52 are separately received in the guiding troughs 412. The eccentric wheel 47 is in contact with the seat 50. By the rotation of the eccentric wheel 47, the guiding rods 52 can move up or down in the guiding troughs 412 to move the seat 50 up or down.

A sealing ring 48 is disposed between the coating chamber 10 and the spindle 49 of the servomotor 42. A sealing element 44 is disposed between the spindle 49 and the sealing ring 48. The sealing ring 48 and the sealing element 44 divide the spindle 49 into an interior portion and an exterior portion to guarantee the vacuum degree of the coating chamber 10. The shaft 45 is synchronously driven with the spindle 49 so as to adjust the seat 50 in vacuum.

When films 60 stacking on the seat 50 is thick enough to possibly scratch the glass, the servomotor 42 is started to rotate the shaft 45. Thus the seat 50 can be moved up or down by rotation of the shaft 50 and the eccentric wheel 47. The shaft 45 can be rotated by the spindle 49 of the servomotor 42 to move the seat 50 up or down. That is, the distance between the seat 50 and the glass 20 is adjustable. When the films further stack to be thicker, the above operation can be performed again. The invention can avoid ceasing the production line for inspection or adjustment. This is very useful for a continuous production line.

Those skilled in the art will appreciate that numerous changes and modifications can be made to the preferred embodiment of the invention, and that such changes and modifications can be made without departing from the spirit of the invention.

What is claimed is:

1. A glass coating system comprising:
a coating chamber;
a conveying unit, located at a lower portion of the coating chamber, having two rollers for conveying a sheet of glass to be coated; and
a support module, located between the rollers, having a seat and an elevator connected to the seat, wherein a distance between the seat and the glass can be adjusted by the elevator.

2. The glass coating system of claim 1, wherein the elevator comprises two fixing bases, a servomotor and an eccentric wheel mechanism, the fixing bases are fastened on a bottom of the coating chamber, the eccentric wheel mechanism is disposed between the two fixing bases, the servomotor is disposed outside the coating chamber, and a spindle of the servomotor is provided with a coupling.

3. The glass coating system of claim 2, wherein the eccentric wheel mechanism comprises a bearing seat between the fixing bases, a shaft is disposed in the bearing seat, the shaft is disposed with an eccentric wheel, and the shaft is connected to the spindle through the coupling so that the shaft can drive the eccentric wheel to rotate.

4. The glass coating system of claim 3, wherein each of the fixing bases is provided with a guiding trough, a bottom of the seat is provided with two guiding rods, the guiding rods are separately received in the guiding troughs, the eccentric wheel is in contact with the seat, the guiding rods is moved up or down in the guiding troughs to move the seat up or down by rotation of the eccentric wheel.

5. The glass coating system of claim 2, wherein a sealing ring is disposed between the coating chamber and the spindle of the servomotor, and a sealing element is disposed between the spindle and the sealing ring.

6. The glass coating system of claim 1, wherein a cathode is arranged at an upper portion of the coating chamber, and the support module is located under the cathode.

7. A support module for a glass coating system, comprising:
a seat; and
an elevator, connected to the seat, comprising two fixing bases, a servomotor and an eccentric wheel mechanism, the fixing bases are fastened on a bottom of the coating chamber, the eccentric wheel mechanism is disposed between the two fixing bases, the servomotor is disposed outside the coating chamber, and a spindle of the servomotor is provided with a coupling.

8. The support module of claim 7, wherein the eccentric wheel mechanism comprises a bearing seat between the fixing bases, a shaft is disposed in the bearing seat, the shaft is disposed with an eccentric wheel, and the shaft is connected to the spindle through the coupling so that the shaft can drive the eccentric wheel to rotate.

9. The support module of claim 8, wherein each of the fixing bases is provided with a guiding trough, a bottom of the seat is provided with two guiding rods, the guiding rods are separately received in the guiding troughs, the eccentric wheel is in contact with the seat, the guiding rods is moved up or down in the guiding troughs to move the seat up or down by rotation of the eccentric wheel.

10. The support module of claim 7, wherein a sealing ring is disposed between the coating chamber and the spindle of the servomotor, and a sealing element is disposed between the spindle and the sealing ring.
